(19) United States
(12) Patent Application Publication
(10) Pub. No.: US 2010/0294978 A1
(43) Pub. Date: Nov. 25, 2010

(54) METAL/INSULATOR NANOGRANULAR MATERIAL AND THIN-FILM MAGNETIC SENSOR

(75) Inventors: Seiichi NAGATA, Nagoya-shi (JP); Shigenobu KOYAMA, Nagoya-shi (JP); Sanji KANIE, Nagoya-shi (JP)

Correspondence Address: GREENBLUM & BERNSTEIN, P.L.C., 1950 ROLAND CLARKE PLACE, RESTON, VA, 20191, US

(73) Assignee: DAIDO TOKUSHUKO KABUSHIKI KAISHA, Aichi (JP)

(21) Appl. No.: 12/782,223

(22) Filed: May 18, 2010

(30) Foreign Application Priority Data
May 20, 2009 (JP) 2009-122492

(51) Int. Cl. H01F 1/04; G01R 33/02

(52) U.S. Cl. 252/62.55; 324/249

(57) ABSTRACT

The present invention provides a metal/insulator nanogranular material including:
ferromagnetic particles having a composition represented by the formula (1)

(Fe₁₋ₓCoₓ)_{100-z}(B_{1-y}Si_{y})_{z} (1)
in which x, y and z each satisfy 0≦x≦1, 0≦y≦1, and 0<z≦20; and
an insulating matrix constituted of an Mg—F compound, the insulating matrix being filled to surround the ferromagnetic particles.

### FIELD OF THE INVENTION

The present invention relates to a metal/insulator nanogranular material and a thin-film magnetic sensor. More particularly, the invention relates to a thin-film magnetic sensor suitable for the acquisition of information on the rotation of an automotive axle, rotary encoder, industrial gear wheel, or the like, the acquisition of information on the stroke position of a hydraulic cylinder/pneumatic cylinder or on the position/speed of the slide of a machine tool, etc., and the acquisition of information on current, e.g., arc current in an industrial welding robot, and for use in geomagnetic azimuth compasses, etc., and also relates to a metal/insulator nanogranular material for use in such a thin-film magnetic sensor.

### BACKGROUND OF THE INVENTION

A magnetic sensor is an electronic device which converts a detected quantity concerning electromagnetic force (e.g., current, voltage, electric power, magnetic field, magnetic flux, etc.), dynamic quantity (e.g., position, velocity, acceleration, displacement, distance, tension, pressure, torque, temperature, humidity, etc.), biochemical quantity, or the like into a voltage through a magnetic field. Magnetic sensors are classified, according to methods of detecting a magnetic field, into hole sensors, anisotropic magnetoresistivity (AMR) sensors, giant magnetoresistivity (GMR: giant MR) sensors, etc.

Of these sensors, GMR sensors have, for example, the following advantages:

(1) compared to AMR sensors, GMR sensors have an exceedingly large maximum value of resistivity change (i.e., an exceedingly large value of MR ratio=Δρ/ρ₀(Δρ=ρ_{H}−ρ₀: ρ_{H} is resistivity at an external magnetic field of H, and ρ₀ is resistivity at an external magnetic field of zero));
(2) compared to hole sensors, change of resistance of GMR sensors depending on the temperature is smaller; and
(3) GMR sensors are suitable for microfabrication because the material having a giant magnetoresistance effect is a thin-film material.

Therefore, GMR sensors are expected to be used as high-sensitivity magnetic microsensors in applications including computers, electric power, motor vehicles, domestic electrical appliances, and portable appliances.

Known materials showing a GMR effect include: metallic artificial lattices constituted of a multilayer film including a ferromagnetic layer (e.g., Permalloy) and a nonmagnetic layer (e.g., Cu, Ag, or Au) or a multilayer film having a four-layer structure composed of an antiferromagnetic layer, ferromagnetic layer (fixed layer), nonmagnetic layer, and ferromagnetic layer (free layer) (so-called “spin valve”); metal/metal nanogranular materials including nanometer-size fine particles of a ferromagnetic metal (e.g., Permalloy) and a grain boundary phase constituted of a nonmagnetic metal (e.g., Cu, Ag, or Au); tunnel junction films in which an MR (magnetoresistivity) effect is produced by a spin-dependent tunnel effect; and metal/insulator nanogranular materials including ferromagnetic fine metal alloy particles of a nanometer size and an insulating matrix constituted of a nonmagnetic insulating material.

Of those materials, the multilayer films represented by spin valves are generally characterized by having high sensitivity in a low-intensity magnetic field. However, the multilayer films have poor stability and low yield because of the necessity of superposing thin films of various materials with high accuracy, and there are limitations in reducing production cost. Therefore, multilayer films of this kind are used entirely in devices having a high value added (e.g., magnetic heads for hard disks), and it is thought to be difficult to apply such multilayer films to magnetic sensors, which encounter competition in cost with the AMR sensors or hole sensors that have a low unit price. In addition, the multilayer films are apt to suffer diffusion between layers and to be deprived of the GMR effect. The multilayer films hence have a serious drawback that the heat resistance thereof is poor.

On the other hand, nanogranular materials generally are easy to produce and have satisfactory reproducibility. Therefore, when the nanogranular materials are applied to magnetic sensors, a cost reduction in magnetic sensors can be attained. In particular, metal/insulator nanogranular materials have, for example, the following advantages:

(1) the materials at room temperature show a high MR ratio exceeding 10% when the composition thereof is optimized:
(2) the materials have an extraordinarily high resistivity ρ, and therefore simultaneously render microminiaturization and power consumption reduction in magnetic sensors possible; and
(3) the materials are usable even in high-temperature environments unlike the spin valve films including an antiferromagnetic film, which have poor heat resistance.
However, the metal/insulator nanogranular materials have a problem that the magnetic sensitivity thereof in a low-intensity magnetic field is considerably low. Therefore, a technique is being employed in which a soft-magnetic thin film is disposed at each end of a giant magnetoresistive thin film to enhance the magnetic sensitivity of the giant magnetoresistive thin film.

Various proposals have hitherto been made on such metal/insulator nanogranular materials and on thin-film magnetic sensors employing the materials.

For example, JP-A-2001-094175 discloses a high-resistivity magnetoresistive film which has a structure including an insulator matrix and nanometer-size magnetic granules dispersed therein and has the composition of Fe₂₆CO₁₂Mg₁₈F₄₄.

The document includes a statement to the effect that a high resistivity is obtained by dispersing magnetic granules of a nanometer size in an insulating matrix constituted of a fluoride.

JP-A-2003-258333 discloses a magnetoresistive film which has a structure including an insulator matrix and nanometer-size magnetic granules dispersed therein and has the composition (Fe_{0.6}CO_{0.4})₄₁Mg₂₁Fe₃₈.

The document includes a statement to the effect that a magnetoresistive film having such a composition has an MR ratio of 12.3% and a temperature coefficient of MR ratio of −260 ppm/° C.

Furthermore, JP-A-2004-063592 discloses a multilayer type magnetoresistance-effect device employing FeCoB as a free-magnetization layer, although this material is not a metal/insulator nanogranular material.

The document includes a statement to the effect that a reversed magnetic field can be enhanced by using FeCoB as a free-magnetization layer.

### SUMMARY OF THE INVENTION

There are cases where metal/insulator nanogranular materials are heated when used in various applications. For example, in the case of the magnetic sensor including a giant magnetoresistive thin film made of a metal/insulator nanogranular material and a yoke made of a soft-magnetic thin film and disposed at each end of the magnetoresistive thin film, a heat treatment is conducted in order to improve the magnetic properties of the yoke.

However, the metal/insulator nanogranular material considerably increases in resistivity upon heating. There is a problem that when the resistivity excessively increases due to heat, the material comes not to produce the magnetoresistance effect.

There are often cases where a plurality of magnetoresistance-effect devices are used to configure a bridge circuit in producing a magnetic sensor. Accordingly, when the magnetoresistance-effect devices considerably differ from each other in the increase in resistivity caused by a heat treatment, this poses a problem that the devices differ in output, resulting in a decrease in the accuracy of magnetic detection.

An object of the invention is to provide a metal/insulator nanogranular material which, even when heated, shows a relatively small increase in resistivity, the resistivity increase being even, as well as a thin-film magnetic sensor employing the material.

Namely, the present invention provides the following items 1 to 5.

1. A metal/insulator nanogranular material comprising: ferromagnetic particles having a composition represented by the formula (1)

(Fe₁₋ₓCoₓ)_{100-z}(B_{1-y}Si_{y})_{z} (1)
wherein x, y and z each satisfy 0≦x≦1, 0≦y≦1, and 0<z≦20; and

an insulating matrix comprising an Mg—F compound, the insulating matrix being filled to surround the ferromagnetic particles.

2. The metal/insulator nanogranular material according to item 1, wherein z satisfies 5≦z≦20.

3. The metal/insulator nanogranular material according to item 1, wherein z satisfies 7≦z≦15.

4. The metal/insulator nanogranular material according to any one of items 1 to 3, wherein y is 0.

5. A thin-film magnetic sensor employing the metal/insulator nanogranular material according to any one of items 1 to 4.

When a given amount of boron and/or silicon is added to an (Mg—F)—FeCo nanogranular material, the nanogranular material comes to have a relatively small increase in resistivity through heating. This brings about evenness of the increase in resistivity. This effect is thought to be produced because the boron and/or silicon inhibits the FeCo ferromagnetic particles from growing during heating.

### BRIEF DESCRIPTION OF THE DRAWINGS

FIG. 1 is a presentation showing relationships between heat treatment temperature and MR ratio (applied magnetic field=4 [kOe]) in MgF₂—(Fe_{0.6}CO_{0.4})_{100-z}B_{z} (0≦z≦20) nanogranular materials.

FIG. 2 is a presentation showing relationships between heat treatment temperature and change ratio in resistance in MgF₂—(Fe_{0.6}CO_{0.4})_{100-z}B_{z} (0≦z≦20) nanogranular materials.

FIG. 3 is a presentation showing a relationship between boron amount z (at %) and change ratio in the average particle diameter of FeCo particles in MgF₂—(Fe_{0.6}CO_{0.4})_{100-z}B_{z} (0≦z≦20) nanogranular materials.

FIG. 4 is a presentation showing relationships between heat treatment temperature and MR ratio (applied magnetic field=4 [kOe]) in MgF₂—(Fe_{0.6}CO_{0.4})_{100-z}Si_{z} (0≦z≦20) nanogranular materials.

FIG. 5 is a presentation showing relationships between heat treatment temperature and change ratio in resistance in MgF₂—(Fe_{0.6}CO_{0.4})_{100-z}Si_{z} (0≦z≦20) nanogranular materials.

FIG. 6 is a presentation showing a relationship between silicon amount z (at %) and change ratio in the average particle diameter of FeCo particles in MgF₂—(Fe_{0.6}CO_{0.4})_{100-z}Si_{z} (0≦z≦20) nanogranular materials.

FIG. 7 is a presentation showing relationships between heat treatment temperature and MR ratio (applied magnetic field=4 [kOe]) in MgF₂—(Fe_{0.6}CO_{0.4})_{90-z′}B₁₀Si_{z′} (0≦z′≦10) nanogranular materials.

FIG. 8 is a presentation showing relationships between heat treatment temperature and change ratio in resistance in MgF₂—(Fe_{0.6}CO_{0.4})_{90-z′}B₁₀Si_{z′} (0≦z′≦10) nanogranular materials.

FIG. 9 is a presentation showing a relationship between silicon amount z′ (at %) and change ratio in the average particle diameter of FeCo particles in MgF₂—(Fe_{0.6}CO_{0.4})_{90-z′}B₁₀Si_{z′} (0≦z′≦10) nanogranular materials.

### BEST MODE FOR CARRYING OUT THE INVENTION

One embodiment of the invention is explained below in detail.

### 1. Metal/Insulator Nanogranular Material

The metal/insulator nanogranular material according to the invention includes ferromagnetic particles and an insulating matrix.

### 1.1. Ferromagnetic Particles

The ferromagnetic particles in the invention are constituted of an Fe—Co alloy as a base and a given amount of boron and/or silicon added thereto. Specifically, the ferromagnetic particles have a composition represented by the following formula (1):

(Fe₁₋ₓCoₓ)_{100-z}(B_{1-y}Si_{y})_{z} (1)

wherein x, y and z each satisfy 0≦x≦1, 0≦y≦1, and 0<z≦20.

In formula (1), x represents the atomic proportion of the cobalt to the iron and cobalt contained in the ferromagnetic particles. The ferromagnetic particles may be ones including iron only or cobalt only, or may be constituted of an Fe—Co alloy. From the standpoint of obtaining a high MR ratio, it is preferred that x be 0 or larger and not larger than 0.9.

In formula (1), y represents the atomic proportion of the silicon to the boron and silicon contained in the ferromagnetic particles. The ferromagnetic particles may be ones containing boron only or silicon only, or may be ones containing both boron and silicon. Boron and silicon each have the function of inhibiting resistivity from increasing through a heat treatment. In particular, boron is more effective than silicon in inhibiting resistivity increase and, hence, produces a high effect even when added in a small amount. From the standpoint of obtaining a high effect with a small addition amount, it is preferred that y be 0.5 or smaller. The value of y is more preferably 0.3 or smaller, even more preferably 0.

In formula (1), z represents the total amount of the boron and silicon (at %) contained in the Fe—Co ferromagnetic particles. By adding boron and/or silicon to Fe—Co ferromagnetic particles, resistivity can be inhibited from increasing through a heat treatment. The value of z is more preferably 5 at % or larger, even more preferably 7 at % or larger.

On the other hand, in case where the value of z is excessively large, MR ratio decreases. Consequently, z must be 20 at % or smaller. The value of z is more preferably 15 at % or smaller.

Boron and silicon have a small atomic radius and are hence apt to penetrate into interstices between the ferromagnetic particles and the insulting matrix. The reason why the addition of boron or silicon inhibits the ferromagnetic particles from growing is thought to be that these elements penetrate through the interface between the ferromagnetic particles and the insulting matrix to prevent the ferromagnetic particles from aggregating together. Besides boron and silicon, examples of elements having the same function as those include C, Al, and P.

In order to inhibit the growth of ferromagnetic particles, an element which is less apt to be diffused by a heat treatment may be rendered present on the surface of the ferromagnetic particles, in place of an element having a small atomic radius. When a less diffusible element is present on the surface of ferromagnetic particles, the ferromagnetic particles are less apt to move in the insulating matrix and the ferromagnetic particles are prevented from aggregating together. Examples of elements having such a function include Ti, V, Zr, Nb, Mo, Hf, Ta, and W.

### 1.2. Insulting Matrix

The insulating matrix is filled to surround the ferromagnetic particles. In other words, the ferromagnetic particles are dispersed in the insulating matrix. In the invention, the insulating matrix is constituted of an Mg—F compound.

The stoichiometric composition of magnesium fluoride is Mg:F=1:2. However, there are cases where deposition of a magnesium fluoride film by sputtering results in a composition different from the stoichiometric composition. In the invention, the term “Mg—F compound” includes both magnesium fluoride having that stoichiometric composition and magnesium fluoride having a composition different from the stoichiometric composition.

Incidentally, when the chemical formula “MgF₂” is used in the invention, not only magnesium fluoride having the stoichiometric composition but also magnesium fluoride having a composition different from the stoichiometric composition is included unless otherwise indicated.

The amount of the insulting matrix affects the properties of the metal/insulator nanogranular material. In general, when the amount of the insulating matrix is too small, the ferromagnetic particles are in contact with each other and no magnetoresistive tunneling effect is obtained. It is therefore preferred that the amount of the insulating matrix is 40 at % or larger.

On the other hand, in case where the amount of the insulting matrix is excessively large, resistivity increases significantly, making it difficult to detect a change in magnetic field as a change in current. Consequently, the amount of the insulating matrix is preferably 70 at % or smaller.

### 2. Process for Producing Metal/Insulator Nanogranular Material

The metal/insulator nanogranular material according to the invention can be produced by forming on an adequate substrate a thin film of a metal/insulator nanogranular material having the composition described above.

Methods for forming the thin film are not particularly limited, and various methods can be used according to purposes.

Examples of methods for forming the thin film include

(1) a method in which a combined target composed of a metal disk including iron, cobalt, etc. and a chip of magnesium fluoride placed on the disk is used to conduct sputtering; and
(2) a method in which a metal target including iron, cobalt, etc. and a magnesium fluoride target are simultaneously used to conduct sputtering.

### 3. Thin-Film Magnetic Sensor

The thin-film magnetic sensor according to the invention employs the metal/insulator nanogranular material according to the invention.

In the case where a thin film (GMR film) of the metal/insulator nanogranular material is used as a magnetic sensor, wiring lines may be connected respectively to both ends of the GMR film to directly detect a current. Alternatively, a pair of yoke constituted of a soft-magnetic material may be disposed at both ends of the GMR film to detect a current through the yoke. In particular, when a pair of yoke constituted of a soft-magnetic material is disposed on both ends of the GMR film, magnetic sensitivity in low-intensity magnetic fields can be improved.

Examples of such soft-magnetic materials include an alloy of 40-90% nickel and iron, Fe₇₄Si₉Al₁₇, Fe₁₂Ni₈₂Nb₆, CO₈₈Nb₆Zr₆ amorphous alloy, (Co₉₄Fe₆)₇₀Si₁₅B₁₅ amorphous alloy, Fe_{75.6}Si_{13.2}B_{8.5}Nb_{1.9}Cu_{0.8}, Fe₈₃Hf₆C₁₁, Fe₈₅Zr₁₀B₅ alloy, Fe₉₃Si₃N₄ alloy, Fe₇₁B₁₁N₁₈ alloy, Fe_{71.3}Nd_{9.6}O_{19.1} nanogranular alloy, CO₇₀Al₁₀O₂₀ nanogranular alloy, and CO₆₅Fe₅Al₁₀O₂₀ alloy.

In the case of a thin-film magnetic sensor including a GMR film of the metal/insulator nanogranular material and a pair of yoke constituted of a soft-magnetic material and disposed at both ends of the film, a heat treatment is usually conducted after yoke formation in order to improve the magnetic properties of the yoke. In general, the higher the heat treatment temperature, the more the properties of the yoke are improved to give a high MR ratio. Meanwhile, in case where the heat treatment temperature is too high, the resistivity of the GMR film becomes exceedingly high, resulting in a decrease, rather than an increase, in MR ratio.

An optimal heat treatment temperature varies depending on the composition of the yoke, required properties, etc. Usually, the heat treatment temperature is 150-300° C.

An optimal heat treatment period is selected according to the heat treatment temperature. In general, the higher the heat treatment temperature, the shorter the time period required for improving magnetic properties. The heat treatment period is usually 0.5-2 hours.

### 4. Effect of Metal/Insulator Nanogranular Material and Thin-Film Magnetic Sensor

In general, when a thin film of a metal/insulator nanogranular material is exposed to heat, the resistivity of the thin film increases. This is thought to be because the ferromagnetic particles grow due to heat and the interparticulate spacing is thereby increased. Excessive growth of the ferromagnetic particles is a cause of a considerable increase in the resistivity of the thin film. Furthermore, uneven growth of the ferromagnetic particles is a cause of enhanced unevenness of the resistivity of the thin film.

In contrast, when a given amount of boron and/or silicon is added to a magnesium fluoride/FeCo nanogranular material, this material has a relatively small increase in resistivity after heating. Moreover, the addition brings about evenness of the increase in resistivity. This is thought to be because the boron and/or silicon inhibits the FeCo ferromagnetic particles from growing during heating.

### EXAMPLES

### Examples 1 to 3 and Comparative Example 1

### 1. Production of Samples

Giant magnetoresistive thin films (GMR films) constituted of a metal/insulator nanogranular material were formed on a substrate. Thereafter, the GMR films were heat-treated. Heat treatment temperatures of 150-450° C. were used.

As the GMR films, use was made of MgF₂—(Fe_{0.6}CO_{0.4})_{100-z}B_{z} nanogranular materials. The following values of z were used: 0 at % (Comparative Example 1), 5 at % (Example 1), 10 at % (Example 2), and 20 at % (Example 3). The GMR films had a thickness of from 200 nm to 1,000 nm.

### 2. Test Methods

### 2.1. Magnetic Properties

The GMR films were examined for MR ratio (applied magnetic field=4 [kOe]). Before and after the heat treatment, the GMR films were examined for resistivity.

### 2.2. Average Particle Diameter

The average particle diameter of the FeCo ferromagnetic particles in each GMR film was determined by fitting a magnetization curve of the GMR film using Langevin's function and a distribution function normalized with logarithm. Details of the procedure are as described in the following treatise: K. Yakushiji, S. Mitani, K. Takanashi, J.-G. Ha and H. Fujimori, J. Magn. Magn. Mater., 212, (2000), 75-81, which is herein incorporated by reference.

### 3. Results

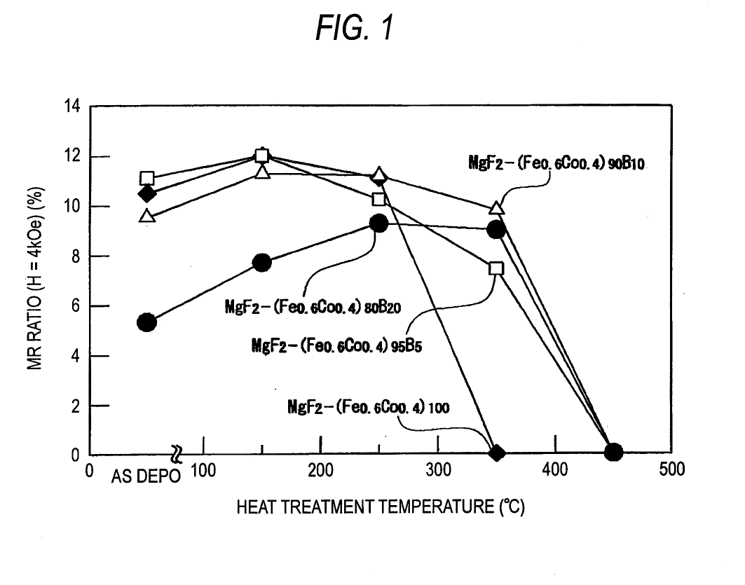

In FIG. 1 are shown relationships between heat treatment temperature and MR ratio (applied magnetic field=4 [kOe]) in the MgF₂—(Fe_{0.6}CO_{0.4})_{100-z}B_{z} (0≦z≦20) nanogranular materials.

The following can be found from FIG. 1:

(1) the sample containing no boron comes to have an MR ratio of zero through 350° C. heat treatment, whereas the samples containing boron show a high MR ratio even after 350° C. heat treatment;
(2) the sample having a boron addition amount of 20 at % is reduced in MR ratio; and
(3) from the standpoint of obtaining a high MR ratio, the addition amount of boron is preferably 5-20 at %, more preferably 7-15 at %.

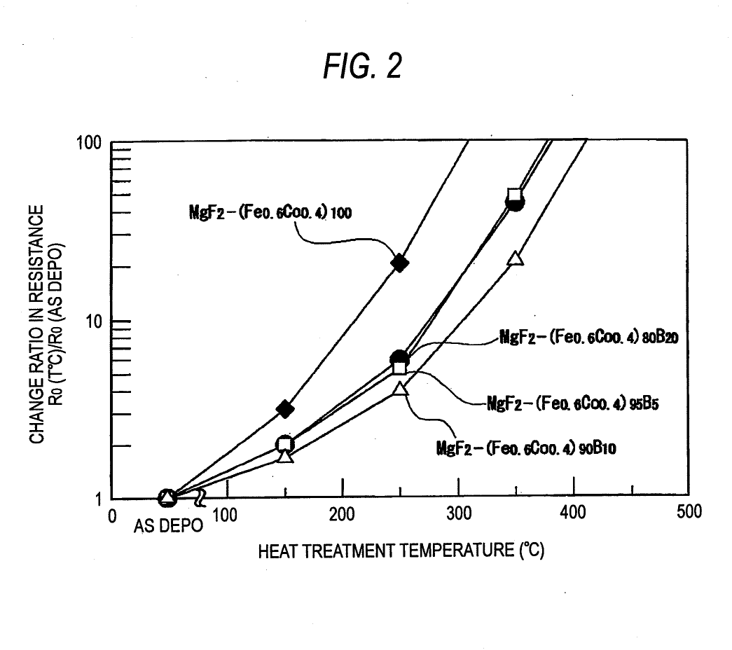

In FIG. 2 are shown relationships between heat treatment temperature and change ratio in resistance in the MgF₂—(Fe_{0.6}CO_{0.4})_{100-z}B_{z} (0≦z≦20) nanogranular materials. The term “change ratio in resistance” herein means the ratio of the zero-field resistance measured after a heat treatment conducted at a heat treatment temperature of T (° C.) (R₀(T° C.)) to the zero-field resistance measured immediately after film deposition (as deposited) (R₀(as depo)) (i.e., the ratio is R₀(T° C.)/R₀(as depo)).

It can be seen from FIG. 2 that the sample containing no boron shows a large change ratio in resistance with heat treatments, whereas the samples containing boron are reduced in change ratio in resistance.

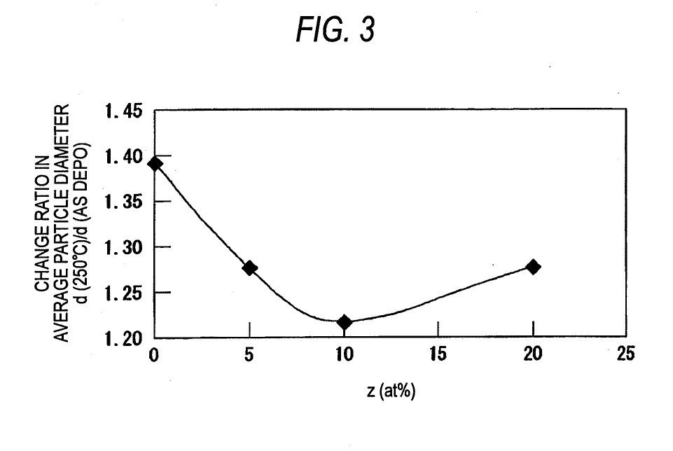

In FIG. 3 is shown a relationship between boron amount z (at %) and change ratio in the average particle diameter of FeCo particles in the MgF₂—(Fe_{0.6}CO_{0.4})_{100-z}B_{z} (0≦z≦20) nanogranular materials.

The term “change ratio in average particle diameter” herein means a value obtained by dividing the average particle diameter measured after 250° C. heat treatment (d(250° C.)) by the average particle diameter measured immediately after film deposition (as deposited) (d(as depo)) (i.e., that value is d(250° C.)/d(as depo)).

The following can be seen from FIG. 3:

(1) although the FeCo ferromagnetic particles increase in average particle diameter through a heat treatment, the addition of boron inhibits the average particle diameter from increasing through the heat treatment; and
(2) from the standpoint of inhibiting the average particle diameter from increasing through heat treatments, the addition amount of boron is preferably 5-20 at %, more preferably 7-15 at %.

From the results given above, it was found that by adding a given amount of boron to FeCo ferromagnetic particles, resistance can be inhibited from increasing through a heat treatment, while maintaining a high MR ratio.

### Examples 4 to 6

### 1. Production of Samples

GMR films constituted of an MgF₂—(Fe_{0.6}CO_{0.4})_{100-z}Si_{z} nanogranular material were produced in the same manner as in Example 1, except that silicon was added in place of boron. The amount of silicon added was 6 at % (Example 4), 10 at % (Example 5), or 20 at % (Example 6). A sample in which the silicon addition amount was 0 at % (Comparative Example 1) was also tested.

### 2. Test Methods

The magnetic properties of each GMR film and the average particle diameter of the FeCo ferromagnetic particles were determined in the same manners as in Example 1.

### 3. Results

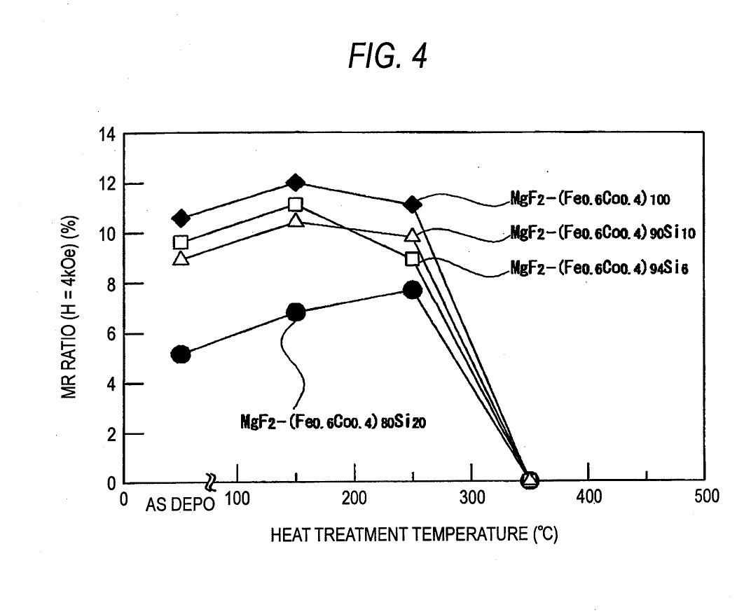

In FIG. 4 are shown relationships between heat treatment temperature and MR ratio (applied magnetic field=4 [kOe]) in the MgF₂—(Fe_{0.6}CO_{0.4})_{100-z}Si_{z} (0≦z≦20) nanogranular materials.

The following can be found from FIG. 4:

(1) the sample having a silicon addition amount of 20 at % is reduced in MR ratio; and
(2) from the standpoint of obtaining a high MR ratio, the addition amount of silicon is preferably 0-15 at %.

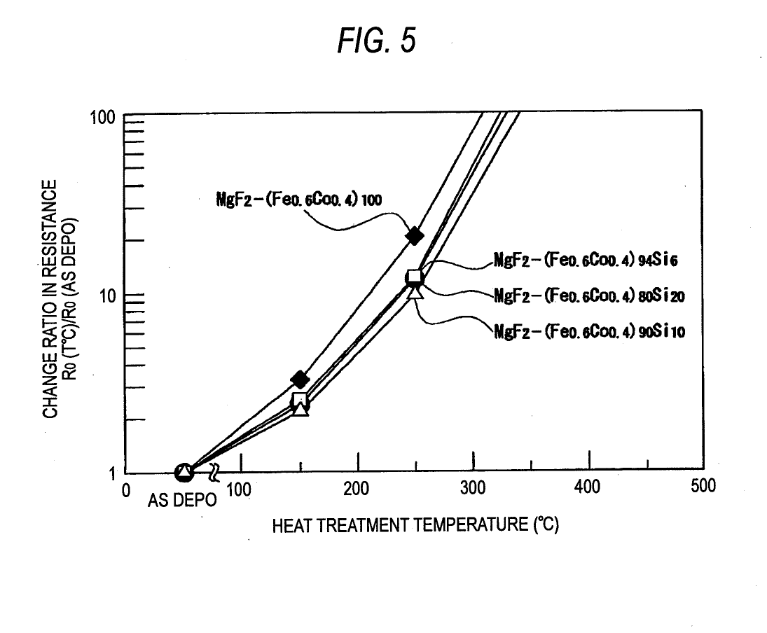

In FIG. 5 are shown relationships between heat treatment temperature and change ratio in resistance in the MgF₂—(Fe_{0.6}CO_{0.4})_{100-z}Si_{z} (0≦z≦20) nanogranular materials.

It can be seen from FIG. 5 that the addition of silicon reduced the change ratio in resistance.

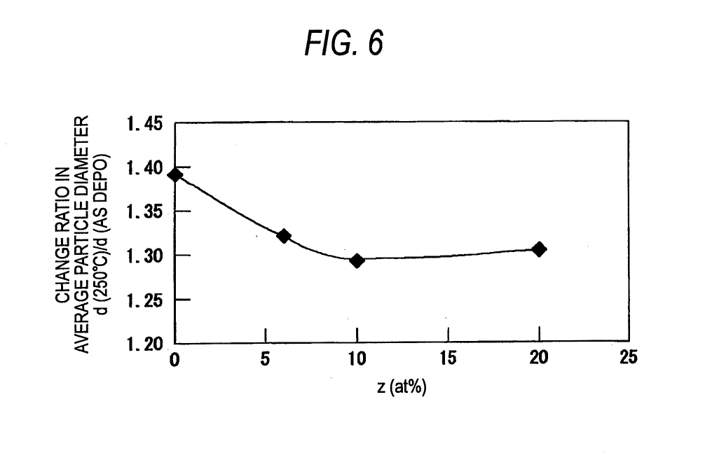

In FIG. 6 is shown a relationship between silicon amount z (at %) and change ratio in the average particle diameter of FeCo particles in the MgF₂—(Fe_{0.6}CO_{0.4})_{100-z}Si_{z} (0≦z≦20) nanogranular materials.

The following can be seen from FIG. 6:

(1) the addition of silicon inhibits the average particle diameter of the FeCo ferromagnetic particles from increasing through the heat treatment;
(2) from the standpoint of inhibiting the average particle diameter from increasing through heat treatments, the addition amount of silicon is preferably 5-20 at %, more preferably 7-15 at %; and
(3) when the change ratios in the average particle diameter of FeCo ferromagnetic particles are compared with respect to the same addition amount, it can be seen that the addition amount of boron is smaller than the addition amount of silicon (boron is more effective in inhibiting particle growth).

From the results given above, it was found that by adding a given amount of silicon to FeCo ferromagnetic particles, resistance can be inhibited from increasing through a heat treatment, while maintaining a high MR ratio.

### Examples 7 and 8

### 1. Production of Samples

GMR films constituted MgF₂—(Fe_{0.6}CO_{0.4})_{90-z′}B₁₀Si_{z′} nanogranular material were produced in the same manner as in Example 1, except that both boron and silicon were added in place of boron alone. The amount of silicon added was 6 at % (Example 7) or 10 at % (Example 8). The GMR film having a boron addition amount of 10 at % (Example 2), which showed most satisfactory properties among the films in which boron alone was added, and the GMR film containing neither boron nor silicon (Comparative Example 1) were also tested.

### 2. Test Methods

The magnetic properties of each GMR film and the average particle diameter of the FeCo ferromagnetic particles were determined in the same manners as in Example 1.

### 3. Results

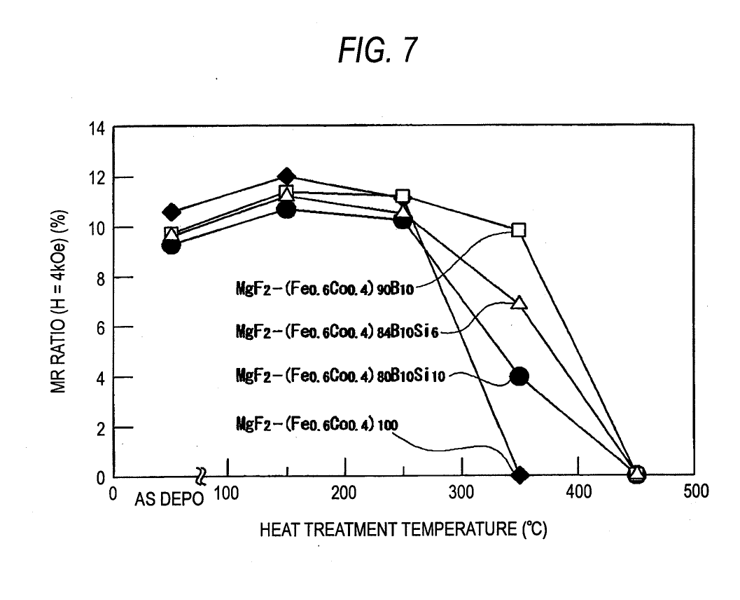

In FIG. 7 are shown relationships between heat treatment temperature and MR ratio (applied magnetic field=4 [kOe]) in the MgF₂—(Fe_{0.6}CO_{0.4})_{90-z′}B₁₀Si_{z′} (0≦z′≦10) nanogranular materials.

The following can be seen from FIG. 7:

(1) the larger the silicon addition amount, the lower the MR ratio; and
(2) the samples of Examples 7 and 8 show substantially the same MR ratios as the sample containing neither boron nor silicon (Comparative Example 1) at the temperatures up to 250° C., and show higher MR ratios at 350° C. than Comparative Example 1.

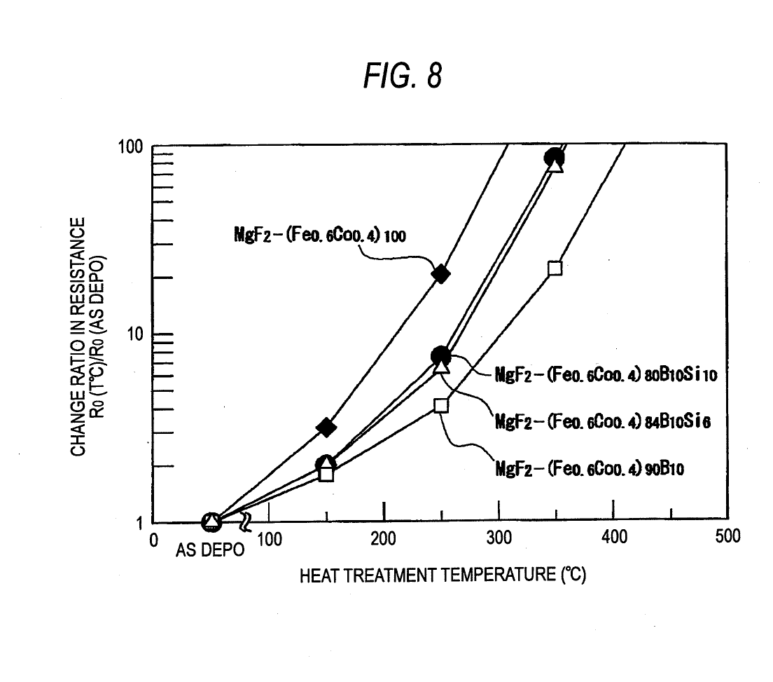

In FIG. 8 are shown relationships between heat treatment temperature and change ratio in resistance in the MgF₂—(Fe_{0.6}CO_{0.4})_{90-z′}B₁₀Si_{z′} (0≦z′=10) nanogranular materials.

The following can be seen from FIG. 8:

(1) the larger the silicon addition amount, the larger the change ratio in resistance; and
(2) compared to the sample containing neither boron nor silicon (Comparative Example 1), each sample shows smaller change ratios in resistance.

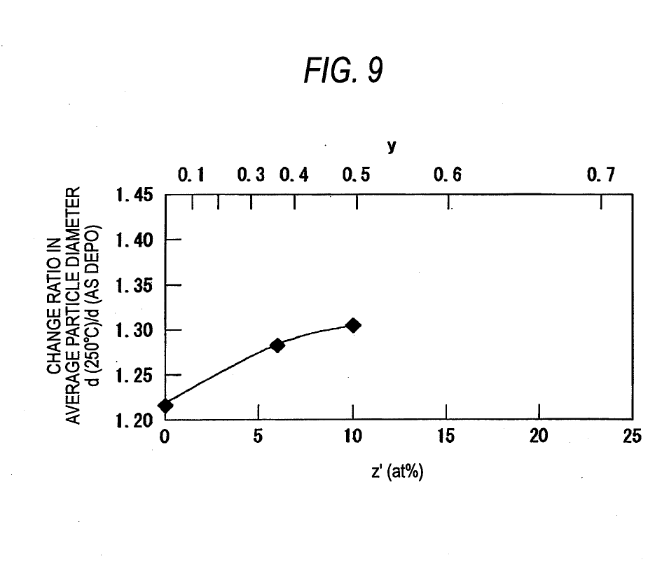

In FIG. 9 is shown a relationship between silicon amount z′ (at %) and change ratio in the average particle diameter of FeCo particles in the MgF₂—(Fe_{0.6}CO_{0.4})_{90-z′}B₁₀Si_{z′} (=MgF₂—(Fe_{0.6}Co_{0.4})_{100-(10+z′)}(B_{1-(z′(10+z′))}Si_{z′/(10+z′)})_{10+z′}) (0≦z′≦10) nanogranular materials.

The following can be seen from FIG. 9:

(1) the larger the silicon addition amount, the larger the change ratio in the average particle diameter of the FeCo ferromagnetic particles through the heat treatment;
(2) compared to the sample containing neither boron nor silicon (Comparative Example 1), each sample shows a smaller change ratio in average particle diameter, i.e., each sample is superior to Comparative Example 1, in which the change ratio is 1.39 times; and
(3) the value of y (=z′/(10+z′)) is preferably 0.5 or smaller, more preferably 0.3 or smaller, even more preferably zero.

From the results given above, it was found that by adding given amounts of boron and silicon in combination to FeCo ferromagnetic particles, resistance can be inhibited from increasing through a heat treatment, while maintaining a high MR ratio.

While embodiments of the invention have been described in detail, the invention should not be construed as being limited to the embodiments in any way and various modifications can be made therein without departing from the spirit of the invention.

The metal/insulator nanogranular material according to the invention can be used as a material for a magnetic sensor, magnetic memory, magnetic head, etc.

The thin-film magnetic sensor according to the invention can be used for the acquisition of information on the rotation of an automotive axle, rotary encoder, industrial gear wheel, or the like, the acquisition of information on the stroke position of a hydraulic cylinder/pneumatic cylinder or on the position/speed of the slide of a machine tool, etc., and the acquisition of information on current, e.g., arc current in an industrial welding robot, and in other applications including geomagnetic azimuth compasses.

The present application is based on Japanese Application No. 2009-122492 filed May 20, 2009, the contents thereof being incorporated herein by reference.

What is claimed is:

1. A metal/insulator nanogranular material comprising:
ferromagnetic particles having a composition represented by the formula (1)
(Fe₁₋ₓCoₓ)_{100-z}(B_{1-y}Si_{y})_{z} (1)
wherein x, y and z each satisfy 0≦x≦1, 0≦y≦1, and 0≦z≦20; and
an insulating matrix comprising an Mg—F compound, the insulating matrix being filled to surround the ferromagnetic particles.

2. The metal/insulator nanogranular material according to claim 1, wherein z satisfies 5≦z≦20.

3. The metal/insulator nanogranular material according to claim 1, wherein z satisfies 7≦z≦15.

4. The metal/insulator nanogranular material according to claim 1, wherein y is 0.

5. The metal/insulator nanogranular material according to claim 2, wherein y is 0.

6. The metal/insulator nanogranular material according to claim 3, wherein y is 0.

7. A thin-film magnetic sensor employing the metal/insulator nanogranular material according to claim 1.
